(19) United States
(12) Patent Application Publication
(10) Pub. No.: US 2021/0166954 A1
(43) Pub. Date: Jun. 3, 2021

(54) METHOD OF RAPID ENCAPSULATION OF MICROELECTRONIC DEVICES

(71) Applicant: Carbon, Inc., Redwood City, CA (US)

(72) Inventors: James Patrick Troise, San Francisco, CA (US); Gurjeev Chadha, Union City, CA (US); Joseph M. DeSimone, Monte Sereno, CA (US)

(21) Appl. No.: 17/264,033

(22) PCT Filed: Jul. 31, 2019
(86) PCT No.: PCT/US2019/044353

§ 371 Date: Jan. 28, 2021

Related U.S. Application Data
(60) Provisional application No. 62/713,273, filed on Aug. 1, 2018.

(51) Int. Cl. H01L 21/56; B33Y 80/00; B33Y 10/00; B29C 64/124; H01L 21/02; H01L 23/31; B81C 1/00; B81B 7/00

(52) U.S. Cl. CPC H01L 21/565; B33Y 80/00; B33Y 10/00; B29C 64/124; B29L 2031/34; H01L 21/568; H01L 23/3114; B81C 1/00333; B81B 7/0077; H01L 21/02057

(57) ABSTRACT

A method of encapsulating at least one object in a polymer shell includes (a) providing a carrier having a release surface and at least one object releasably secured thereto, each object having a heighth dimension and a width dimension; (b) providing a light polymerizable resin, the resin supported on a light transmissive window; (c) advancing each object on the carrier into the light polymerizable resin to a position spaced away from the window by a distance sufficient to maintain a dead zone or release layer of unpolymerized resin directly on the window; (d) forming a first portion of the polymer shell around each object by projecting patterned light through the window; (e) forming a subsequent portion of a polymer shell on or around each object by advancing the object on the carrier away from the window and projecting patterned light through the window; and (f) repeating step (e) until each object is encapsulated in a polymer shell.

### FIELD OF THE INVENTION

The present invention concerns additive manufacturing in general, and particularly concerns the use of stereolithographic techniques to package or encapsulate microelectronic devices.

### BACKGROUND OF THE INVENTION

G. Boubault et al., A new microsystem packaging approach using 3D printing encapsulation process (IEEE 68^{th} Electronics Components and Technology Conference 2018), describes the use of a 3D printer for packaging microelectronic devices, including custom packages that contain a cavity. The technique described is said to offer new approaches to building custom packages for such devices. However, the technique used a “top down” 3D printer, where the objects being fabricated sink downward into a pool of light polymerizable resin as the package is produced around the object. Such techniques ordinarily employ a “sweeper” to spread and flattin the resin along the X and Y axis, as a mandatory step (Id at 120, first column). However, such a sweeper could not be used due in the described process because the objects being encapsulated necessarily projected above the surface of the resin, requiring instead the use of a relaxation time before UV irradiation. Unfortunately, introducing relaxation times into the process for the purpose of smoothing the surface of a (generally viscous) resin pool slows the process. Accordingly, new approaches for the more rapid encapsulation of microelectronic devices, that retain additional advantages offered by additive manufacturing techniques, are needed.

### SUMMARY OF THE INVENTION

As discussed below, we find that objects can be encapsulated by a “bottom up” additive manufacturing technique, even though such techniques for encapsulation purposes requires penetration of light into the resin to greater depths (to form lower portions of the encapsulating shell) than heretofore generally practiced.

In some embodiments, a method of encapsulating at least one object in a polymer shell includes (a) providing a carrier having a release surface and at least one object releasably secured thereto, each object having a heighth dimension and a width dimension; (b) providing a light polymerizable resin, the resin supported on a light transmissive window; (c) advancing each object on the carrier into the light polymerizable resin to a position spaced away from the window by a distance sufficient to maintain a dead zone or release layer of unpolymerized resin directly on the window; (d) forming a first portion of the polymer shell around each object by projecting patterned light through the window; (e) forming a subsequent portion of a polymer shell on or around each object by advancing the object on the carrier away from the window and projecting patterned light through the window; and (f) repeating step (e) until each object is encapsulated in a polymer shell.

In some embodiments, the object comprises a microelectronic or optoelectronic substrate (e.g., a silicon chip(s), wafer, integrated circuit, microelectromechanical systems (MEMS) device, etc.). In some embodiments, the object comprises multiple interconnected devices.

In some embodiments, the method includes the step of cleaning the object (e.g., by washing) after it is encapsulated in the polymer shell.

In some embodiments, the object is secured to the carrier by an intervening releasable substrate, optionally but in some embodiments preferably with the polymer shell adhered to the releasable substrate.

In some embodiments, the object has a height of at least 100, 200, 300, 400, or 500 microns, up to a height of 1, 2, 3, or 4 millimeters.

In some embodiments, the resin comprises a dual cure resin (e.g., an epoxy dual cure resin).

In some embodiments, the forming step (f) is carried out while maintaining a gradient of polymerization zone in the resin between the release layer and the previously formed portion of the polymer shell.

In some embodiments, the window is permeable to an inhibitor of polymerization (e.g., oxygen), and the release layer is maintained passing the inhibitor from the window into the release layer.

In some embodiments, the polymer shell is layerless.

In some embodiments, the at least one object comprises a plurality of objects, and optionally wherein the polymer shells of the objects differ from one another.

In some embodiments, the polymer shell includes a structural feature (e.g., a channel, void, identifying feature, interlocking feature, or combination thereof), for example to control the thermal capacitance or temperature profile of the package, identify the package, etc.

In some embodiments, an article of manufacture includes (a) a substrate; (b) a plurality of objects on the substrate; and (c) a polymer shell encapsulating each object formed on object by the process of bottom-up stereolithography.

In some embodiments, each object comprises a microelectronic or optoelectronic device, or MEMS device.

In some embodiments, the polymer shells include at least one structural feature (e.g., a channel, void, identifying feature, interlocking feature, or combination thereof).

In some embodiments, the polymer shells differ from one another.

### BRIEF DESCRIPTION OF THE DRAWINGS

FIG. 1 schematically illustrates an early stage of a process of the present invention.

FIG. 2 schematically illustrates a stage of a process of the present invention subsequent to the stage of FIG. 1.

FIG. 3 schematically illustrates a stage of a process of the present invention subsequent to the stage of FIG. 2.

FIG. 4 schematically illustrates a stage of a process of the present invention subsequent to that of FIG. 3.

FIG. 5 schematically illustrates a stage of a process of the present invention subsequent to that of FIG. 4.

FIG. 6 schematically illustrates a stage of a process of the present invention similar to that of FIG. 5, except that different encapsulating polymer shells are produced.

### DETAILED DESCRIPTION OF ILLUSTRATIVE EMBODIMENTS

The present invention is now described more fully hereinafter with reference to the accompanying drawings, in which embodiments of the invention are shown. This invention may, however, he embodied in many different forms and should not be construed as limited to the embodiments set forth herein; rather these embodiments are provided so that this disclosure will be thorough and complete and will fully convey the scope of the invention to those skilled in the art.

As used herein, the term “and/or” includes any and all possible combinations of one or more of the associated listed items, as well as the lack of combinations when interpreted in the alternative (“or”).

1. Polymerizable Liquids (Resins).

Resins. Conventional (or “single cure”) resins, or dual cure resins, can be used to carry out the invention.

Dual cure additive manufacturing resins are described in, for example, Rolland et al., U.S. Pat. Nos. 9,676,963; 9,598,606; and 9,453,142, and in Wu et al., US Patent Application Pub. No. US2017/0260418, the disclosures of which are incorporated herein by reference. Constituents of such resins may be used with the prepolymers of the present invention, or the prepolymers of the present invention may be added to such resins, as described further above and below.

Example dual cure resins include, but are not limited to, Carbon Inc. EPU 40, EPU 41, FPU, RPU 70, SIL 30, and EPX 82 resins, all available from Carbon Inc. 1089 Mills Way, Redwood City, Calif. 94063 USA.

Additive manufacturing. The resins may be used to make three-dimensional objects, in a “light” cure (typically by additive manufacturing) which in some embodiments generates a “green” intermediate object, followed in some embodiments by a second (typically heat) cure of that intermediate object.

Techniques for additive manufacturing are known. Suitable techniques include bottom-up or top-down additive manufacturing, generally known as stereolithography. Such methods are known and described in, for example, U.S. Pat. No. 5,236,637 to Hull, U.S. Pat. Nos. 5,391,072 and 5,529,473 to Lawton, U.S. Pat. No. 7,438,846 to John, U.S. Pat. No. 7,892,474 to Shkolnik, U.S. Pat. No. 8,110,135 to El-Siblani, U.S. Patent Application Publication No. 2013/0292862 to Joyce, and US Patent Application Publication No. 2013/0295212 to Chen et al. The disclosures of these patents and applications are incorporated by reference herein in their entirety.

In some embodiments, the intermediate object is formed by continuous liquid interface production (CLIP). CLIP is known and described in, for example, PCT Application Nos. PCT/US2014/015486 (published as U.S. Pat. No. 9,211,678 on Dec. 15, 2015); PCT/US2014/015506 (also published as U.S. Pat. No. 9,205,601 on Dec. 8, 2015), PCT/US2014/015497 (also published as U.S. Pat. No. 9,216,546 on Dec. 22, 2015), and in J. Tumbleston, D. Shirvanyants, N. Ermoshkin et al., Continuous liquid interface production of 3D Objects, Science 347, 1349-1352 (published online 16 Mar. 2015). See also R. Janusziewcz et al., Layerless fabrication with continuous liquid interface production, Proc. Natl. Acad. Sci. USA 113, 11703-11708 (Oct. 18, 2016). In some embodiments, CLIP employs features of a bottom-up three-dimensional fabrication as described above, but the irradiating and/or said advancing steps are carried out while also concurrently maintaining a stable or persistent liquid interface between the growing object and the build surface or window, such as by: (i) continuously maintaining a dead zone of polymerizable liquid in contact with said build surface, and (ii) continuously maintaining a gradient of polymerization zone (such as an active surface) between the dead zone and the solid polymer and in contact with each thereof, the gradient of polymerization zone comprising the first component in partially cured form. In some embodiments of CLIP, the optically transparent member comprises a semipermeable member (e.g., a fluoropolymer), and the continuously maintaining a dead zone is carried out by feeding an inhibitor of polymerization through the optically transparent member, thereby creating a gradient of inhibitor in the dead zone and optionally in at least a portion of the gradient of polymerization zone. Other approaches for carrying out CLIP that can be used in the present invention and potentially obviate the need for a semipermeable “window” or window structure include utilizing a liquid interface comprising an immiscible liquid (see L. Robeson et al., WO 2015/164234, published Oct. 29, 2015), generating oxygen as an inhibitor by electrolysis (see I Craven et al., WO 2016/133759, published Aug. 25, 2016), and incorporating magnetically positionable particles to which the photoactivator is coupled into the polymerizable liquid (see J. Rolland, WO 2016/145182, published Sep. 15, 2016).

After the intermediate three-dimensional object is formed, it is optionally cleaned, optionally dried (e.g., air dried) and/or rinsed (in any sequence). It is then further cured, preferably by heating (although further curing may in some embodiments be concurrent with the first cure, or may be by different mechanisms such as contacting to water, as described in US Patent No. 9,453,142 to Rolland et al.).

2. Cleaning or Washing.

Objects as described above can be cleaned in any suitable apparatus, in some embodiments with a wash liquid as described above and below, and in other embodiments by wiping (with an absorbent, air blade, etc.) spinning, or variations thereof

Wash liquids that may be used to carry out the present invention include, but are not limited to, water, organic solvents, and combinations thereof (e.g., combined as co-solvents), optionally containing additional ingredients such as surfactants, chelants (ligands), enzymes, borax, dyes or colorants, fragrances, etc., including combinations thereof. The wash liquid may be in any suitable form, such as a solution, emulsion, dispersion, etc.

In some preferred embodiments, where the residual resin has a boiling point of at least 90 or 100° C. (e.g., up to 250 or 300° C., or more), the wash liquid has a boiling point of at least 30° C., but not more than 80 or 90° C. Boiling points are given herein for a pressure of 1 bar or 1 atmosphere.

In some embodiments, the wash liquid consists of a 50:50 (volume:volume) solution of water and an alcohol organic solvent such as isopropanol (2-propanol).

Examples of hydrofluorocarbon solvents that may be used to carry out the present invention include, but are not limited to, 1,1,1,2,3,4,4,5,5,5-decafluoropentane (Vertrel® XF, DuPont™ Chemours), 1,1,1,3,3-Pentafluoropropane, 1,1,1,3,3-Pentafluorobutane, etc.

Examples of hydrochlorofluorocarbon solvents that may be used to carry out the present invention include, but are not limited to, 3,3-Dichloro-1,1,1,2,2-pentafluoropropane, 1,3-Dichloro-1,1,2,2,3-pentafluoropropane, 1,1-Dichloro-1-fluoroethane, etc., including mixtures thereof.

Examples of hydrofluoroether solvents that may be used to carry out the present invention include, but are not limited to, methyl nonafluorobutyl ether (HFE-7100), methyl nonafluoroisobutyl ether (HFE-7100), ethyl nonafluorobutyl ether (HFE-7200), ethyl nonafluoroisobutyl ether (HFE-7200), 1,1,2,2-tetrafluoroethyl-2,2,2-trifluoroethyl ether, etc., including mixtures thereof. Commercially available examples of this solvent include Novec 7100 (3M), Novec 7200 (3M).

Examples of volatile methylsiloxane solvents that may be used to carry out the present invention include, but are not limited to, hexamethyldisiloxane (OS-10, Dow Corning), octamethyltrisiloxane (OS-20, Dow Corning), decamethyltetrasiloxane (OS-30, Dow Corning), etc., including mixtures thereof.

Other siloxane solvents (e.g., NAVSOLVE™ solvent) that may be used to carry out the present invention include but are not limited to those set forth in U.S. Pat. No. 7,897,558.

In some embodiments, the wash liquid comprises an azeotropic mixture comprising, consisting of, or consisting essentially of a first organic solvent (e.g., a hydrofluorocarbon solvent, a hydrochlorofluorocarbon solvent, a hydrofluoroether solvent, a methylsiloxane solvent, or a combination thereof; e.g., in an amount of from 80 or 85 to 99 percent by weight) and a second organic solvent (e.g., a C1-C4 or C6 alcohol such as methanol, ethanol, isopropanol, tert-butanol, etc.; e.g., in an amount of from 1 to 15 or 20 percent by weight). Additional ingredients such as surfactants or chelants may optionally be included. In some embodiments, the azeotropic wash liquid may provide superior cleaning properties, and/or enhanced recyclability, of the wash liquid. Additional examples of suitable azeotropic wash liquids include, but are not limited to, those set forth in U.S. Pat. Nos. 6,008,179; 6,426,327; 6,753,304; 6,288,018; 6,646,020; 6,699,829; 5,824,634; 5,196,137; 6,689,734; and 5,773,403, the disclosures of which are incorporated by reference herein in their entirety.

When the wash liquid includes ingredients that are not desired for carrying into the further curing step, in some embodiments the initial wash with the wash liquid can be followed with a further rinsing step with a rinse liquid, such as water (e.g., distilled and/or deionized water), or a mixture of water and an alcohol such as isopropanol.

3. Further Curing.

After washing, the object is in some embodiments further cured, preferably by heating or baking.

Heating may be active heating (e.g., in an oven, such as an electric, gas, solar oven or microwave oven, heated bath, or combination thereof), or passive heating (e.g., at ambient (room) temperature). Active heating will generally be more rapid than passive heating and in some embodiments is preferred, but passive heating such as simply maintaining the intermediate at ambient temperature for a sufficient time to effect further cure is in some embodiments preferred.

In some embodiments, the heating step is carried out at at least a first (oven) temperature and a second (oven) temperature, with the first temperature greater than ambient temperature, the second temperature greater than the first temperature, and the second temperature less than 300° C. (e.g., with ramped or step-wise increases between ambient temperature and the first temperature, and/or between the first temperature and the second temperature). In some embodiments, the heating step is carried out at at least a first (oven) temperature and a second (oven) temperature, with the first temperature greater than ambient temperature, the second temperature greater than the first temperature, and the second temperature less than 300° C. (e.g., with ramped or step-wise increases between ambient temperature and the first temperature, and/or between the first temperature and the second temperature).

For example, the intermediate may be heated in a stepwise manner at a first temperature of about 70° C. to about 150° C., and then at a second temperature of about 150° C. to 200 or 250° C., with the duration of each heating depending on the size, shape, and/or thickness of the intermediate. In another embodiment, the intermediate may be cured by a ramped heating schedule, with the temperature ramped from ambient temperature through a temperature of 70 to 150° C., and up to a final (oven) temperature of 250 or 300° C., at a change in heating rate of 0.5° C. per minute, to 5° C. per minute. (See, e.g., U.S. Pat. No. 4,785,075).

In some embodiments, the heating step is carried out in an inert gas atmosphere. Inert atmosphere ovens are known, and generally employ an atmosphere enriched in nitrogen, argon, or carbon dioxide in the oven chamber. Suitable examples include but are not limited to those available from Grieve Corporation, 500 Hart Road Round Lake, Ill. 60073-2898 USA, Davron Technologies, 4563 Pinnacle Lane, Chattanooga, Tenn. 37415 USA, Despatch Thermal Processing Technology, 8860 207th Street, Minneapolis, Minn. 55044 USA, and others.

In other embodiments, the heating step is carried out in an inert liquid bath. Suitable inert liquids may be aqueous liquids (i.e., pure water, salt solutions, etc.), organic liquids (e.g., mineral oil, fluorinated, perfluorinated, and polysiloxane organic compounds such as perfluorohexane, perfluoro(2-butyl-tetrahydrofurane), perfluorotripentylamine, etc. (commercially available as PERFLUORINERT® inert liquids from 3M Company), and mixtures thereof. These inert liquids can be deoxygenated if necessary, such as by bubbling an inert gas such as nitrogen through the liquid, by boiling the inert liquid, by mixing oxygen-scavenging agents with the inert liquid medium (or contacting them to one another), etc., including combinations thereof (see, e.g., U.S. Pat. No. 5,506,007).

In some embodiments, the further curing or heating step (whether carried out in a liquid or gas fluid) is carried out at an elevated pressure (e.g., elevated sufficiently to reduce volatilization or out-gassing of residual monomers, prepolymers, chain extenders, and/or reactive diluents, etc.). Suitable pressure ranges are from 10 or 15 psi to 70 or 100 psi, or more.

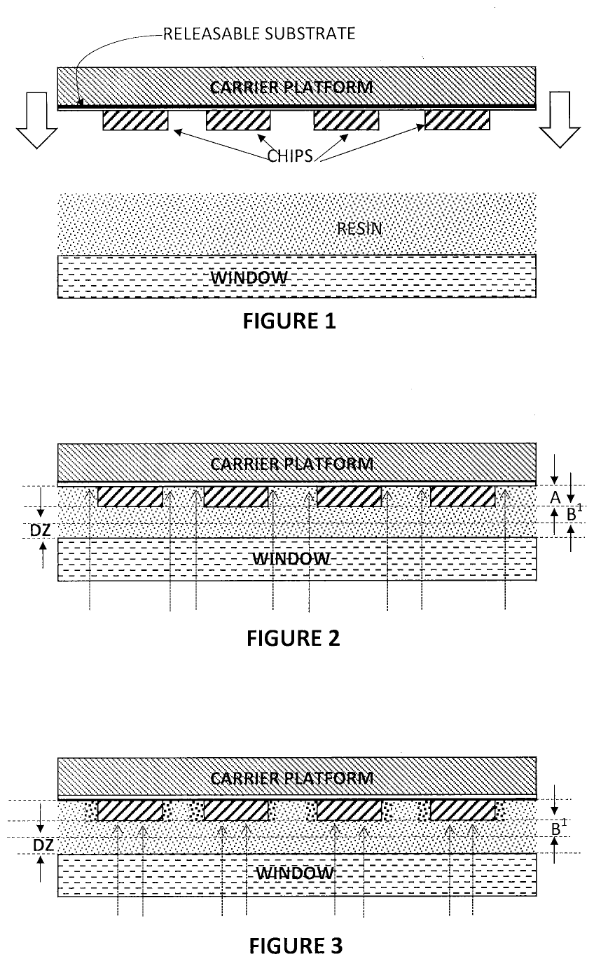

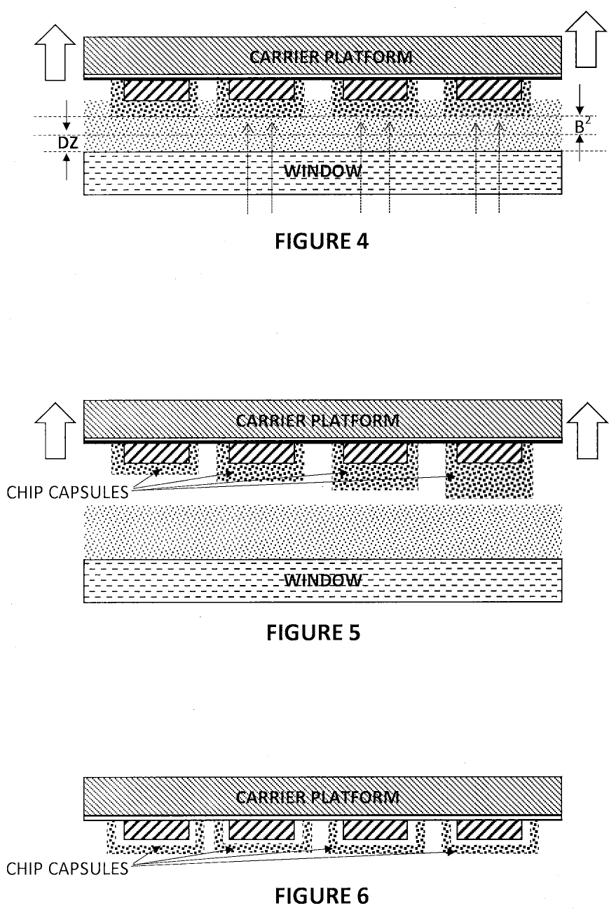

A non-limiting example of a process of the present invention is shown, in sequence, in FIGS. 1-5. The carrier platform and window of a bottom-up stereolithography apparatus (e.g., a Carbon M1 apparatus, available from Carbon Inc. 1089 Mills Way, Redwood City, Calif. 94063) are provided, with the window (or window cassette in a Carbon M1 apparatus) loaded with a suitable resin (for example, Carbon Inc. EPX 82 epoxy dual cure resin, also available from Carbon Inc.).

A releasable substrate is secured to the carrier platform, and microelectronic chips/integrated circuit chips secured to the releasable substrate. The carrier platform is then advanced towards the resin, immersing the chips in the resin, but leaving a suitable gap for a dead zone (DZ), for a polymerization region A around and alongside the chips (extending down to the releasable substrate), and a polymerization region B¹ beneath the chips. Photopolymerization of the resin by light (dashed arrows) is initially carried out deep in the resin, in region A, followed by photopolymerization of region B¹. Subsequent portions of the encapsulating polymer shells (chip capsules) are formed with subsequent projections B², until formation of the chip capsules is complete. The capsules may differ from one another in a variety of respects or structural features, as needed (as described above), but in FIG. 5 this difference is represented simply as a difference in size.

In addition, the capsule may include heat dissipation elements, such as a fractal heats ink.

In some embodiments, multiple interconnected chips, microelectronic sysytems, optoelectronic devices, MEMS devices, or combinations thereof are packaged in the same encapsulating polymer shell, to allow for shortened interconnect paths between those multiple devices. The shortened interconnects enabled by the present invention aid in reducing inductances and result in better I/O performance.

FIG. 6 is similar to FIG. 5, except that different capsules are formed: in this case, capsules including a cavity or void between the capsule itself, and the object being encapsulated. Drain holes may be provided in the capsule (not shown) for cleaning or draining excess unpolymerized resin, and the drain holes plugged if desired in a subsequent polymerization step, by application of an adhesive or sealant, or any other suitable technique.

The foregoing is illustrative of the present invention, and is not to be construed as limiting thereof The invention is defined by the following claims, with equivalents of the claims to be included therein.

1. A method of encapsulating at least one object in a polymer shell, comprising:
(a) providing a carrier having a release surface and at least one object releasably secured thereto, each said object having a heighth dimension and a width dimension;
(b) providing a light polymerizable resin, said resin supported on a light transmissive window;
(c) advancing each said object on the carrier into the light polymerizable resin to a position spaced away from said window by a distance sufficient to maintain a dead zone or release layer of unpolymerized resin directly on said window;
(d) forming a first portion of said polymer shell around each said object by projecting patterned light through said window;
(e) forming a subsequent portion of a polymer shell on or around each said object by advancing said object on the carrier away from the window and projecting patterned light through said window; and
(f) repeating step (e) until each said object is encapsulated in a polymer shell.

2. The method of claim 1, wherein said object comprises a microelectronic or optoelectronic substrate.

3. The method of claim 1, further comprising the step of cleaning said object after it is encapsulated in said polymer shell.

4. The method of claim 1, wherein said object is secured to said carrier by an intervening relea.sable substrate, optionally but in some embodiments preferably with said polymer shell adhered to said releasable substrate.

5. The method of claim 1, wherein said object has a height of at least 100 microns 4 millimeters.

6. The method of claim 1, wherein said resin comprises a dual cure resin.

7. The method of claim 1, wherein said forming step (f) is carried out while maintaining a gradient of polymerization zone in said resin between said release layer and the previously formed portion of said polymer shell.

8. The method of claim 1, wherein said window is permeable to an inhibitor of polymerization, and said release layer is maintained passing said inhibitor from said window into said release layer.

9. The method of claim 1, wherein said polymer shell is layerless.

10. The method of claim 1, wherein said at least one object comprises a plurality of objects, and optionally wherein said polymer shells of said objects differ from one another.

11. The method of claim 1, wherein said polymer shell includes a structural feature to control the thermal capacitance or temperature profile of the package, identify the package, etc.

12. The method of claim 1, wherein the object comprises multiple interconnected devices.

13. An article of manufacture, comprising:
(a) a substrate;
(b) a plurality of objects on said substrate; and
(c) a polymer shell encapsulating each said object formed on said object by the process of bottom-up stereolithography.

14. The article of claim 13, wherein each said object comprises a, microelectronic or optoelectronic device, or MEMS device.

15. The article of claim 13, wherein said polymer shells include at least one structural feature.

16. The article of claim 13, wherein said polymer shells differ from one another.

17. The article of claim 13, wherein the object comprises multiple interconnected devices.

18. The method of claim 2, wherein said microelectronic or optoelectronic substrate comprises a silicon chip(s), wafer, integrated circuit, microelectromechanical systems (MEMS) device, etc.

19. The article of claim 15, wherein said at least one structural feature comprises a channel, void, identifying feature, interlocking feature, or combination thereof.
